(19) United States
(12) Patent Application Publication
(10) Pub. No.: US 2015/0136450 A1
(43) Pub. Date: May 21, 2015

(54) TOUCH PANEL AND METHOD OF MANUFACTURING THE SAME

(71) Applicant: SAMSUNG ELECTRO-MECHANICS CO., LTD., Suwon (KR)

(72) Inventors: Sung HAN, Suwon (KR); Yang Je Lee, Suwon (KR)

(73) Assignee: SAMSUNG ELECTRO-MECHANICS CO., LTD., Suwon (KR)

(21) Appl. No.: 14/185,433

(22) Filed: Feb. 20, 2014

(30) Foreign Application Priority Data
Nov. 18, 2013 (KR) 10-2013-0139820

(51) Int. Cl. G06F 1/16; H05K 3/00; G06F 3/044

(52) U.S. Cl. CPC G06F 1/1643; G06F 3/044; H05K 3/0058
USPC 174/255; 216/40

(57) ABSTRACT

There are provided a touch panel and a method of manufacturing the same. The touch panel includes: a substrate; and a plurality of fine conductive lines, each of the fine conductive lines including a first black layer formed to have a predetermined pattern, a metal layer formed in accordance with the first black layer, and a second black layer formed on the upper and side surfaces of the metal layer.

### CROSS-REFERENCE TO RELATED APPLICATION

This application claims the benefit of Korean Patent Application No. 10-2013-0139820 filed on Nov. 18, 2013, with the Korean Intellectual Property Office, the disclosure of which is incorporated herein by reference.

### BACKGROUND

The present disclosure relates to a touch panel and a method of manufacturing the same.

A touch sensing device such as a touchscreen or a touch pad is attached to a display device to provide a user with an intuitive data input method and has recently been widely used in various electronic devices such as cellular phones, personal digital assistants (PDAs) and navigation devices. Particularly, as demand for smartphones has recently increased, touchscreens have been increasingly employed since they provide users with various data input methods in a limited form factor.

Touchscreens used in portable devices may be mainly divided into resistive type touchscreens and capacitive-type touchscreens, depending on the way in which a touch is sensed. Among these types of touchscreen, the capacitive-type touchscreen has advantages of a relatively long lifespan and ease of implementing various input manners and gestures, and thus it has been employed more and more frequently. The capacitive-type touchscreen is especially conducive for implementing a multi-touch interface as compared to a resistive type touchscreen, and thus it is widely used in smartphones and the like.

A capacitive-type touchscreen includes a plurality of electrodes having a predetermined pattern and the electrodes define a plurality of nodes in which changes in capacitance is generated by a user's touch. The nodes deployed on a two-dimensional plane generate changes in self-capacitance or changes in mutual-capacitance by a touch. Coordinates of the touch may be calculated by applying a weighted average method or the like to the changes in capacitance generated in the nodes. In existing touch panels, a sensing electrode to sense a touch is commonly formed of indium tin oxide (ITO). In the case of ITO, however, indium is a rare-earth element and is thus expensive, such that it is not economically competitive. Further, world indium reserves are expected to be depleted within 10 years and indium will thus not be easily available. For these reasons, research into forming an electrode using opaque fine conductive lines is on-going. The electrode formed using fine conductive lines is advantageous in that it has much better electric conductivity than ITO or conductive polymer and is easily available. However, the electrode formed using fine conductive lines has a problem in that a color of metal or light reflected from metal causes the fine conductive lines to be visible to users when such fine conductive lines are used as electrodes for a touchscreen.

### RELATED ART DOCUMENT

(Patent Document 1) Korean Patent Laid-Open Publication No. 2011-0089423

### SUMMARY

An aspect of the present disclosure may provide a touch panel having a black layer formed on a metal layer so as to make fine conductive lines less visible.

An aspect of the present disclosure may also provide a method of manufacturing a touch panel in which a mask pattern and an adhesive film formed on an etched area of a metal film may be removed together.

According to an aspect of the present disclosure, a touch panel may include: a substrate; an a plurality of fine conductive lines, each of the fine conductive lines including a first black layer formed to have a predetermined pattern, a metal layer formed in accordance with the first black layer, and a second black layer formed on the upper and side surfaces of the metal layer.

The first black layer may be an adhesive film attaching the metal layer to the substrate.

The second black layer may be formed by performing a plating process.

The second black layer may be formed of black nickel.

The adhesive film may be colored using paint or a pigment.

According to another aspect of the present disclosure, a method of manufacturing a touch panel may include: stacking a substrate, an adhesive film, and a metal film sequentially; forming a photoresist on the metal film; forming a predetermined mask pattern by performing exposure and development on the photoresist; forming a metal layer by etching the metal film to have the mask pattern; and removing the adhesive film formed on an etched area of the metal film, and the mask pattern.

The method may further include forming a black layer on the side and upper surfaces of the metal layer.

The adhesive film may be colored using paint or a pigment.

The metal film may be attached to the adhesive film using a carrier film.

The forming of the metal layer may include etching the metal film using a tenting process.

The black layer may be formed of black nickel.

The black layer may be formed by performing a plating process.

The adhesive film formed on an etched area of the metal film, and the mask pattern may be removed using sodium hydroxide.

The adhesive film formed on an etched area of the metal film, and the mask pattern may be removed together therewith.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view showing an appearance of an electronic device including a touch panel according to an exemplary embodiment of the present disclosure;

FIG. 2 is a front view of a touch panel according to an exemplary embodiment of the present disclosure;

FIG. 3 is a front view of a touch panel according to another exemplary embodiment of the present disclosure;

FIG. 4 is a cross-sectional view of a touch panel according to an exemplary embodiment of the present disclosure; and

FIGS. 5A through 5I are views for illustrating a process of manufacturing a touch panel according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

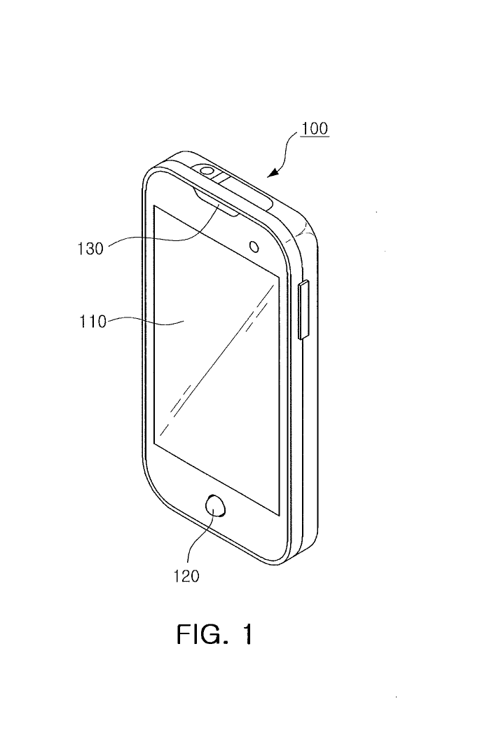

FIG. 1 is a perspective view showing an outer casing of an electronic device including a touch panel, according to an exemplary embodiment of the present disclosure.

Referring to FIG. 1, the electronic device 100 according to the exemplary embodiment may include a display device 110 for displaying an image, an input unit 120, an audio unit 130 for outputting sound, and a touchscreen device integrated with the display device 110. A touch panel may be included in the touchscreen device.

As shown in FIG. 1, it is common in mobile devices that a touchscreen device is integrated with a display device, and such a touchscreen device needs to have light transmittance high enough for an image displayed on the display device to be viewed.

Accordingly, such a touchscreen device may be implemented by forming an electrode with a conductive material on a transparent substrate formed of a film such as polyethylene terephthalate (PET), polycarbonate (PC), polyethersulfone (PES), polyimide (PI), polymethylmethacrylate (PMMA), and cyclo-olefin polymer (COP), soda glass, or tempered glass. In a bezel area of the display device, wiring patterns connected to electrodes formed of a transparent, conductive material are arranged, and the wire patterns are shielded by the bezel area so that they are not visible.

Since the touchscreen device according to the exemplary embodiment is of a capacitive-type, the touchscreen device may include a plurality of electrodes having a predetermined pattern. Further, the touchscreen device may include a capacitance sensing circuit to sense changes in capacitance generated in the plurality of electrodes, an analog-digital converting circuit to convert an output signal from the capacitance sensing circuit into a digital value, and a calculating circuit to determine if a touch is made using the converted digital value.

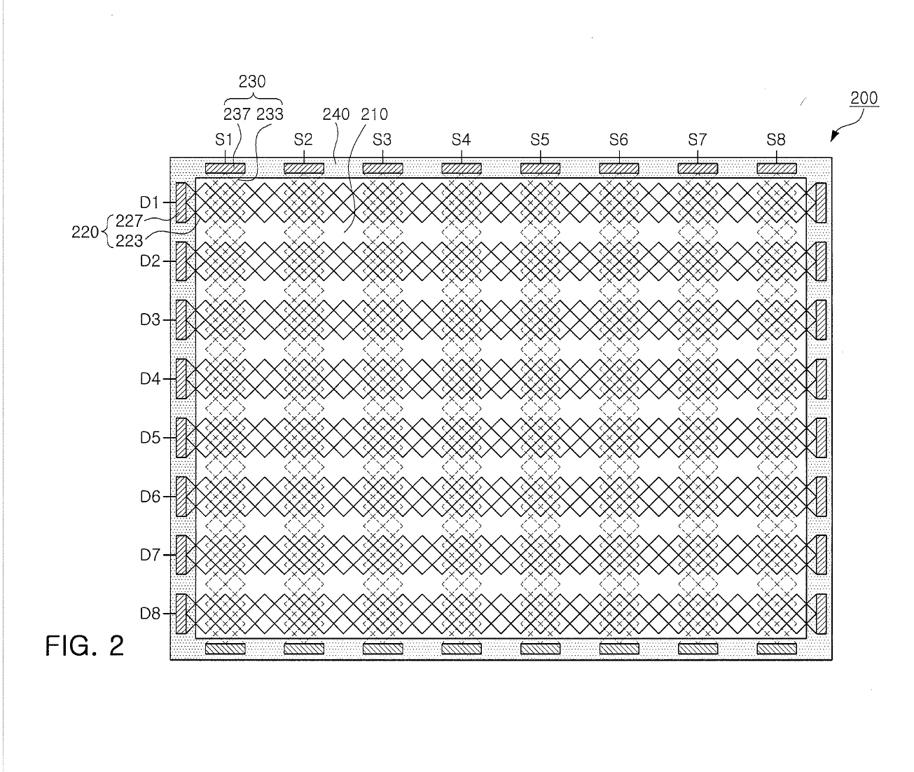

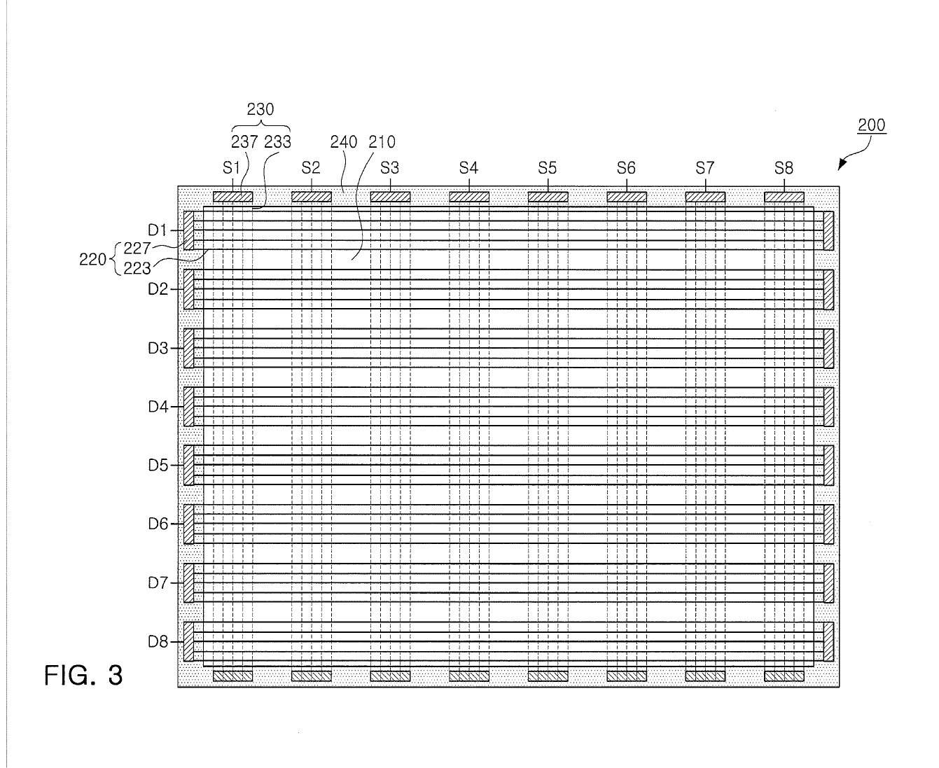

FIG. 2 is a front view of a touch panel according to an exemplary embodiment of the present disclosure; and FIG. 3 is a front view of a touch panel according to another exemplary embodiment of the present disclosure.

Referring to FIG. 2, a touch panel 200 according to the exemplary embodiment may include a substrate 210 and a plurality of electrodes 220 and 230 provided on the substrate 210. Although not shown in FIG. 2, each of the plurality of electrodes 220 and 230 may be electrically connected to a flexible circuit board attached to one side of the substrate 210 through connective wiring and a bonding pad. The flexible circuit board may have a controller integrated circuit mounted thereon so as to detect a sensing signal generated in the plurality of electrodes 220 and 230, and may determine whether a touch has occurred based on the detected sensing signal.

The substrate 210 may be a transparent substrate on which the plurality of electrodes 220 and 230 are to be formed. Accordingly, as described above, the substrate 210 maybe formed of films formed of a material such as polyethylene terephthalate (PET), polycarbonate (PC), polyethersulfone (PES), polyimide (PI), polymethylmethacrylate (PMMA), a cyclo-olefin polymer (COP), soda glass, or tempered glass.

The plurality of electrodes 220 and 230 may include first electrodes 220 extending in the x-axis direction, and second electrodes 230 extending in the y-axis direction.

The first electrodes 220 and the second electrodes 230 may be provided on the same surface or different surfaces of the substrate 210. When the first and second electrodes 220 and 230 are provided on the same surface of the substrate 210, the first electrodes 220 and the second electrodes 230 may have insulation layers partially formed at intersection points therebetween.

Alternatively, the first electrodes 220 and the second electrodes 230 may be provided on different surfaces so as to intersect each other, as will be appreciated.

A device, electrically connected to the plurality of electrodes 220 and 230 to sense a touch, detects changes in capacitance generated in the plurality of electrodes 220 and 230 by a touch to sense the touch occurrence, based on the detected change in capacitance.

The first electrodes 220 may be connected to channels defined as D1 to D8 in the controller integrated circuit to receive predetermined driving signals, and the second electrodes 230 may be connected to channels defined as S1 to S8 to detect changes in capacitance generated between the first electrodes 220 and the second electrodes 230. Here, the controller integrated circuit may use changes in the capacitance as a sensing signal to determine whether touch has occurred.

The plurality of electrodes 220 and 230 may include a plurality of fine conductive lines 223 and 233, and pads 227 and 237 electrically connected to the plurality of fine conductive lines 223 and 233 at the terminals thereof.

Typically, the plurality of fine conductive lines 223 and 233 is formed in a mesh pattern, such that patterning marks are less visible in the region where indium-tin oxide (ITO) electrodes exist and transparency of a touch panel may be improved.

Although the plurality of fine conductive lines 223 and 233 included in the plurality of electrodes 220 and 230 is formed in a diamond shape or a quadrangular shape in FIG. 2, it is apparent that the shape of the plurality of fine conductive lines 223 and 233 is not limited thereto but may be formed in any shape that is obvious to and easily conceived by those skilled in the art such as a hexagonal shape, an octagonal shape, a diamond shape and a random shape. In FIG. 3, for example, the plurality of fine conductive lines 223 and 233 are formed in a linear manner.

In the regions where pads 227 and 237 electrically connected to the plurality of fine conductive lines 223 and 233 are provided, a print layer 240 may be provided on the substrate 210 in order to hide the pads 227 and 237 typically formed of an opaque metal.

The pads 227 and 237 are provided on the print layer 240 provided at the periphery of the substrate 210, and the pads 227 and 237 come in contact with the plurality of fine conductive lines 223 and 233 on the print layer 240.

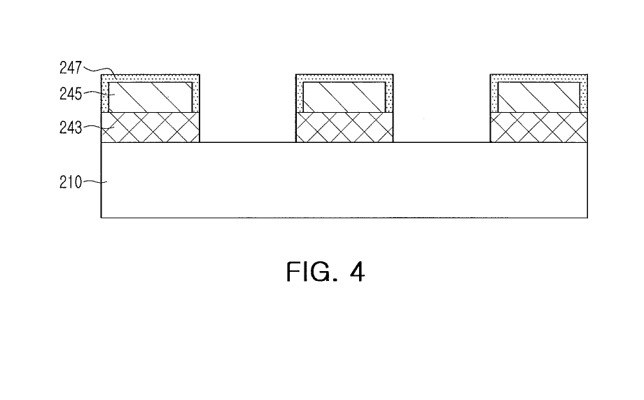

FIG. 4 is a cross-sectional view of a touch panel according to an exemplary embodiment of the present disclosure. Referring to FIG. 4, the touch panel according to the exemplary embodiment may include a substrate 210, and a plurality of fine conductive lines 223 and 233 provided on one surface of the substrate 210.

The plurality of fine conductive lines 223 and 233 may include a first black layer 243, a metal layer 245, and a second black layer 247. The first black layer 243 may be formed on one surface of the substrate in a mesh pattern, and the metal layer 245 may be formed in accordance with the first black layer 243. In addition, the second black layer 247 may be formed on the upper and side surfaces of the metal layer.

The metal layer 245 may be formed of one of Ag, Al, Cr, Ni, Mo, and Cu, or an alloy thereof . By forming the plurality of electrodes 220 and 230 with metal, the resistance value of an electrode may be reduced to thereby improve conductivity and detection sensitivity.

When the metal layer 245 is formed of metal, however, the metal layer 245 may be visible to users due to its unique color or reflection of light. In this regard, the first black layer 243 is formed on the lower surface of the metal layer 245, such that the metal layer 245 may be less visible to users when seen from the other surface of the substrate 210.

In addition, by forming the second black layer 247 on the side and upper surfaces of the metal layer 245, the metal layer 245 may be less visible to users when viewed from the one surface of the substrate.

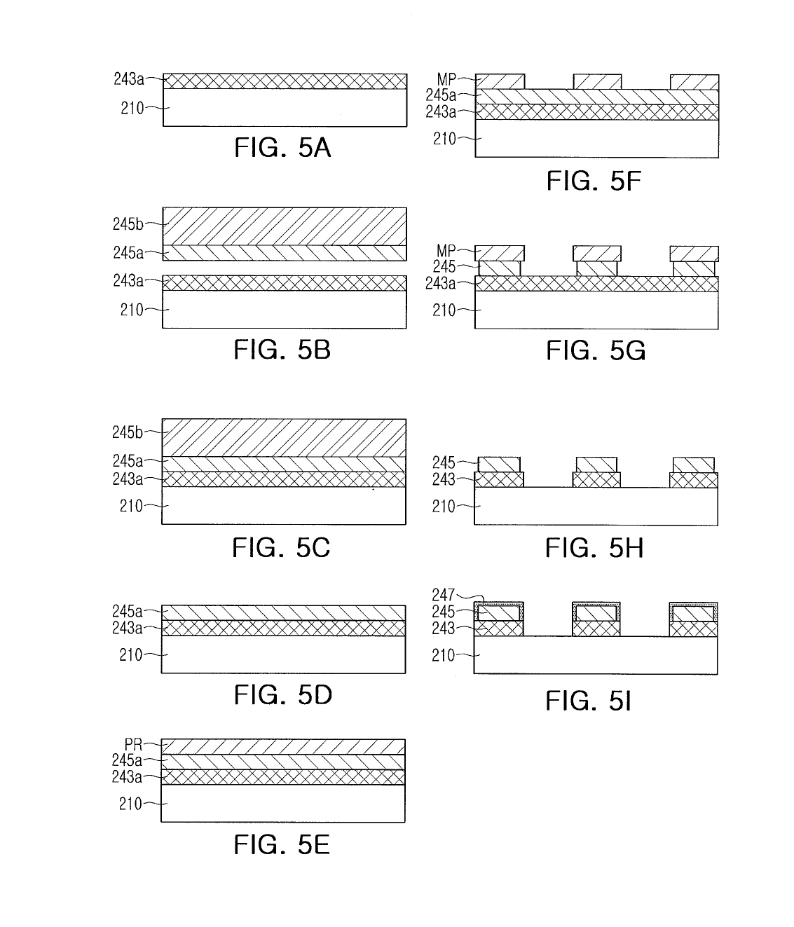

FIGS. 5A through 5I are views for illustrating a process of manufacturing a touch panel according to an exemplary embodiment of the present disclosure. Hereinafter, the process of manufacturing a touch panel according the exemplary embodiment will be described with reference to FIGS. 5A through 5I.

An adhesive film 243a, colored using paint or a pigment, is stacked on one surface of a substrate 210 (see FIG. 5A), and then a metal film 245a is attached on the adhesive film 243a using a carrier film 245b (see FIGS. 5A and 5B). The adhesive film 243a may be formed of acryl-based, urethane-based, epoxy-based, silane-based, amine-based or amide-based material and may be removed using sodium hydroxide (NaOH).

The metal film 245a is produced together with the carrier film 245b during a process, and the carrier film 245b is removed from the metal film 245a after the metal film 245a is attached to the adhesive film 243a in a later process, such that the metal film 245a is attached to the substrate 210. Because the metal film 245a has a significantly reduced thickness of from 1.5 μm to 4.0 μm, it may be difficult to process, and if it is solely produced and attached on the substrate, steps or bubbles may occur. According the exemplary embodiment, the problem may be overcome using the carrier film 245b.

Then, the carrier film 245b is removed (see FIG. 5D), photoresist layer PR is formed on the metal film 245a, and then a mask pattern MP is formed by performing exposure and development (see FIG. 5F).

Subsequently, the metal film 245a on which the mask pattern MP is formed is etched so as to form the metal layer 245 (see FIG. 5G). The etching process may be performed using a tenting process.

After the metal layer 245 is formed, the mask pattern MP is removed. At this time, the adhesive film 243a formed on the etched area of the metal film 245a is also removed, to form the first black layer 243 (see FIG. 5H). Sodium hydroxide (NaOH) may be used as a stripper.

The mask pattern MP and the adhesive film 243a formed on an opening area are removed together, such that the manufacturing process may be simplified. In addition, the adhesive film 243a may be removed using a stripper such as sodium hydroxide, such that damage to the metal layer 245 may be decreased.

Then, the second black layer 247 may be formed on the side and upper surfaces of the metal layer 245 by electroplating or electrolessplating. The second black layer 247 may be implemented using black nickel (see FIG. 5I).

As set forth above, according to exemplary embodiments of the present disclosure, a black layer is formed on a metal layer so as to make fine conductive lines less visible.

In addition, a mask pattern and an adhesive film formed on an etched area of a metal film may be removed together so as to simplify the manufacturing process.

Further, sodium hydroxide is used as a stripper, such that damage to a metal layer may be decreased.

While exemplary embodiments have been shown and described above, it will be apparent to those skilled in the art that modifications and variations could be made without departing from the spirit and scope of the present disclosure as defined by the appended claims.

What is claimed is:

1. A touch panel, comprising:
a substrate; and
a plurality of fine conductive lines, each of the fine conductive lines including a first black layer formed to have a predetermined pattern, a metal layer formed in accordance with the first black layer, and a second black layer formed on the upper and side surfaces of the metal layer.

2. The touch panel of claim 1, wherein the first black layer is an adhesive film attaching the metal layer to the substrate.

3. The touch panel of claim 1, wherein the second black layer is formed by performing a plating process.

4. The touch panel of claim 1, wherein the second black layer is formed of black nickel.

5. The touch panel of claim 2, wherein the adhesive film is colored using paint or a pigment.

6. A method of manufacturing a touch panel, comprising:
stacking a substrate, an adhesive film, and a metal film sequentially;
forming a photoresist on the metal film;
forming a predetermined mask pattern by performing exposure and development on the photoresist;
forming a metal layer by etching the metal film to have the mask pattern; and
removing the adhesive film formed on an etched area of the metal film, and the mask pattern.

7. The method of claim 6, further comprising:
forming a black layer on the side and upper surfaces of the metal layer.

8. The method of claim 6, wherein the adhesive film is colored using paint or a pigment.

9. The method of claim 6, wherein the metal film is attached to the adhesive film using a carrier film.

10. The method of claim 6, wherein the forming of the metal layer includes etching the metal film using a tenting process.

11. The method of claim 7, wherein the black layer is formed of black nickel.

12. The method of claim 7, wherein the black layer is formed by performing a plating process.

13. The method of claim 6, wherein the adhesive film formed on the etched area of the metal film, and the mask pattern are removed using sodium hydroxide.

14. The method of claim 6, wherein the adhesive film formed on the etched area of the metal film, and the mask pattern are removed together therewith.
